(19) United States
(12) Patent Application Publication
(10) Pub. No.: US 2009/0136877 A1
(43) Pub. Date: May 28, 2009

(54) METHOD FOR ORGANIC MATERIAL LAYER FORMATION

(75) Inventor: Naotoshi Suganuma, Kyoto (JP)

Correspondence Address: RABIN & Berdo, PC, 1101 14TH STREET, NW, SUITE 500, WASHINGTON, DC, 20005, US

(73) Assignees: PIONEER CORPORATION, Tokyo (JP); HITACHI ,LTD., Tokyo (JP); ROHM CO., LTD., Kyoto (JP)

(21) Appl. No.: 12/065,441

(22) PCT Filed: Aug. 29, 2006
(86) PCT No.: PCT/JP2006/316991

§ 371 Date: Feb. 29, 2008

(30) Foreign Application Priority Data
Aug. 30, 2005 (JP) 2005-249550

(51) Int. Cl. G03F 7/20

(52) U.S. Cl. 430/325

(57) ABSTRACT

An organic material layer formation method capable of realizing the formation of an ultra microscopic pattern while maintaining an electrical characteristic of an organic material layer is provided. This method includes the steps of forming a resist in a reversal pattern of an organic material layer pattern to be formed on a substrate, applying a surface treatment onto an exposed area exposed from the resist on a surface of the substrate to enhance adhesion to an organic material, forming an organic material layer on the resist and the exposed area, and selectively dissolving the resist with an aqueous solution having selectivity between the organic material and the resist, to lift off the organic material layer on the resist along with the resist.

### TECHNICAL FIELD

The present invention relates to a method for forming a pattern of a layer including an organic material such as an organic semiconductor material, on a substrate.

### BACKGROUND ART

In a manufacturing process of an organic semiconductor device using an organic material layer as a semiconductor active layer, a thin film of an organic material is formed on a substrate such as a glass substrate or a silicon substrate. For the formation of the thin film, generally, a vacuum evaporation method is applied.

More specifically, a vapor deposition source is disposed inside a vacuum chamber, and the substrate on which the thin film is to be formed is disposed so as to face the vapor deposition source. Moreover, a shadow mask is disposed between the substrate and the vapor deposition source. A microscopic opening corresponding to a pattern of the thin film to be formed on the substrate is formed in the shadow mask. Material molecules, which evaporate at the vapor deposition source and fly toward the substrate, pass through the opening of the shadow mask, and reach the substrate surface to adhere to it, which forms the pattern of the thin film of the organic material.

### Patent Document 1: Japanese Unexamined Patent Publication No. 2004-214015

### Patent Document 2: Japanese Unexamined Patent Publication No. 08-37233

### Patent Document 3: Japanese Unexamined Patent Publication No. 06-37117

### DISCLOSURE OF THE INVENTION

### Problem to be Solved by the Invention

However, by the aforementioned method using a shadow mask, it is impossible to form an ultra microscopic pattern of an organic material layer, and there is a limit of a pattern in the order of several μm for miniaturization. Accordingly, this method may not be necessarily suitable for miniaturization and high-integration of an element using an organic material.

On the other hand, it may be conceivable that a lift-off technology in which an unnecessary film portion is removed along with a resist on a substrate for patterning of an organic material layer.

However, in a general lift-off technology, an organic solvent is used in the final process of dissolving a resist. There is the risk that this organic solvent erodes an organic material layer on a substrate, which deteriorates the electrical characteristic thereof. Even if the organic material layer is hardly soluble in the organic solvent, the organic solvent exerts a considerable effect particularly on the electrical characteristic of the organic material layer in a microscopic pattern.

Therefore, it is an object of the present invention to provide an organic material layer formation method capable of realizing the formation of an ultra microscopic pattern (which is preferably a pattern in the order of submicron scale less than or equal to one micrometer) while maintaining an electrical characteristic of an organic material layer.

### Solution of the Problem

An organic material layer formation method of the present invention is for forming a pattern of an organic material layer on a substrate, and the method includes the steps of forming a resist in a reversal pattern of an organic material layer pattern to be formed on the substrate, applying a surface treatment onto an exposed area exposed from the resist on a surface of the substrate to enhance adhesion to an organic material, forming an organic material layer on the resist and the exposed area, and dissolving the resist with an aqueous solution having selectivity between the organic material and the resist, to lift off the organic material layer on the resist along with the resist. The “substrate” may be a substrate in which an insulating film, a metal film, and the like is formed on its surface. The term “substrate surface” in this case is an uppermost surface of the substrate on which the film is formed.

According to this method, a lift-off process of the organic material layer is performed by selectively dissolving the resist by using an aqueous solution having selectivity between the organic material and the resist. The erosion of the organic material layer by the aqueous solution is negligibly slight, and therefore, even when the organic material layer is developed to be an ultra microscopic pattern (for example, a pattern in the order of submicron scale less than or equal to one micrometer), the effect onto the electrical characteristic thereof is negligible. Further, because the adhesion between the substrate and the organic material layer at the portion exposed from the resist is enhanced due to the surface treatment before the organic material layer is formed, it is possible to suppress a necessary portion of the organic material layer from being peeled off from the substrate during a lift-off process. In this way, it is possible to form an accurate pattern of the organic material layer on the substrate.

It is preferable that the method further includes an entire resist exposure process of exposing all of the resist on the substrate before performing a lift-off process (preferably before forming an organic material layer) to induce a chemical change in the resist so that it becomes soluble in the aqueous solution.

In this method, by exposing the entire surface of the resist before performing a lift-off process, it is possible to increase solubilizing/insolubilizing selectivity between the organic material layer and the resist with respect to the aqueous solution used during the lift-off process. In accordance therewith, it is possible to form a more accurate pattern of the organic material layer.

Further, in a case in which several types of organic material layers are formed on the substrate, it is easy to secure the selectivity between the several types of organic material layers and the resist. Therefore, it becomes possible to perform a lift-off process for the several types of organic material layers in one attempt.

The aqueous solution is preferably an alkaline aqueous solution (preferably, an alkaline developer).

Generally, a resist is designed to be soluble in an alkaline aqueous solution, and in a development process after the exposure, an alkaline developer is frequently used. Accordingly, by using an alkaline aqueous solution in the lift-off process, it is possible to increase the selectivity of the resist for the organic material layer, which makes it possible to perform a precise lift-off process.

On the exposed area, when one or more of silicon oxide, alumina, and silicon oxide nitride is exposed from the resist, it is preferable that the surface treatment includes a surface treatment using a silane coupling agent.

According to this method, one or more of silicon oxide, alumina, and silicon oxide nitride is exposed from the resist, and a surface treatment (an adhesion enhancing treatment) using a silane coupling agent is applied onto the exposed portion at which those materials are exposed. When an organic material layer is formed after the surface treatment, the organic material layer is attached firmly to the exposed area. Accordingly, it is possible to effectively prevent a necessary portion of the organic material layer from being peeled off in the following lift-off process.

As examples of the silane coupling agent, HMDS (hexamethyldisilazane) and OTS (octadecyltrichlorosilane) can be mentioned.

When gold is exposed on the exposed area, it is preferable that the surface treatment includes a surface treatment using a thiol compound.

According to this method, by a surface treatment using a thiol compound, an organic material layer subsequently formed is firmly adhered to the gold portion exposed on the exposed area. In accordance therewith, it is possible to suppress or prevent the organic material layer on the surface of the gold portion from being peeled off in the following lift-off process.

For example, when gold is exposed along with one or more of silicon oxide, alumina and silicon oxide nitride from the exposed area, it is preferable that the surface treatment includes both of a surface treatment using a silane coupling agent (an adhesion enhancing treatment) and a surface treatment using a thiol compound (an adhesion enhancing treatment).

The foregoing and other objects, features and effects of the present invention will appear more fully from the following description of examples taken with reference to the accompanying drawings.

### BRIEF DESCRIPTION OF THE DRAWINGS

FIG. 1 is a sectional view schematically showing a construction of an organic semiconductor light emitting element to which a method according to a first embodiment of the present invention is applied.

FIG. 2 is a graph showing an example of operating characteristics of the organic semiconductor light emitting element of FIG. 1.

FIGS. 3A to 3F are schematic sectional views showing a method for manufacturing the organic semiconductor light emitting element in the order of steps.

FIG. 4 is a schematic sectional view for explanation of a construction of an organic semiconductor light emitting element to which a method according to a second embodiment of the present invention is applied.

FIGS. 5A to 5H are schematic sectional views showing a method for manufacturing the organic semiconductor light emitting element of FIG. 4 in the order of steps.

FIG. 6 is a schematic sectional view showing a construction of an organic semiconductor light emitting element to which a method according to a third embodiment of the present invention is applied.

FIGS. 7A to 7E are schematic sectional views showing a method for manufacturing the organic semiconductor light emitting element of FIG. 6 in the order of steps.

FIG. 8 is a schematic sectional view showing a construction of an organic semiconductor light emitting element to which a method according to a fourth embodiment of the present invention is applied.

FIGS. 9A to 9E are schematic sectional views showing a method for manufacturing the organic semiconductor light emitting element of FIG. 8 in the order of steps.

FIGS. 10A and 10B are schematic sectional views for explanation of a problem that protrusions are formed on the edge parts of an organic material layer.

FIGS. 11A and 11B are schematic sectional views for explanation of a method for suppressing protrusions on the edge parts of the organic material layer.

FIG. 12 is a schematic sectional view for explanation of another method for suppressing protrusions on the edge parts of the organic material layer.

### DESCRIPTION OF THE SYMBOLS

1 Gate electrode
2 Silicon oxide film
3 Electron-injection electrode
4 Hole-injection electrode
5 Organic semiconductor part
6 N-type organic semiconductor material layer
7 P-type organic semiconductor material layer
8 Organic light emitting material layer
10 Interelectrode region
11 Intermediate part
12 PN-junction region
15 Gate control circuit
16 Biasing circuit
20 Photoresist
21 Photomask
21a Opening
23 Photoresist
24 Photomask
24a Opening
33 Photoresist
34 Photomask
34a Opening
34b Opening
35 Gap
40 Substrate
41 Organic semiconductor transistor
42 Gate electrode
43 Gate insulating film
45 Organic semiconductor material layer
46 Electrode
47 Electrode
48 Channel region
50 Photoresist
51 Photomask
51a Opening
60 Substrate
61 Resist film
62 Organic material layer
63 Protrusion
64 Side wall

### BEST MODE FOR CARRYING OUT THE INVENTION

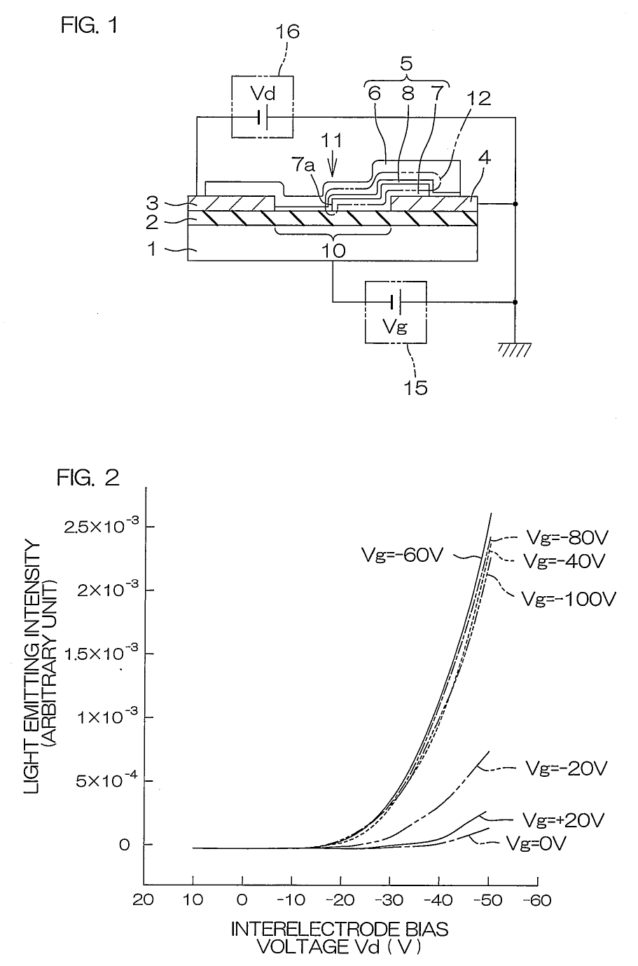

FIG. 1 is a sectional view schematically showing a construction of an organic semiconductor light emitting element to which a method according to a first embodiment of the present invention is applied. This organic semiconductor light emitting element is an element having a basic structure as an FET (field effect transistor). This organic semiconductor light emitting element includes a gate electrode 1 composed of an impurity diffused layer formed by injecting an N-type impurity in high concentration into a surface part of a silicon substrate, an silicon oxide film 2 serving as an insulating film laminated on the gate electrode 1, a pair of electrodes 3 and 4 formed with a predetermined space (for example, 10 μm) on the silicon oxide film 2, and an organic semiconductor part 5 disposed so as to contact the pair of electrodes 3 and 4.

One of the pair of electrodes 3 and 4 is an electron-injection electrode 3 to inject electrons into the organic semiconductor part 5, and the other one is a hole-injection electrode 4 to inject holes into the organic semiconductor part 5.

The organic semiconductor part 5 recombines the electrons injected from the electron-injection electrode 3 and the holes injected from the hole-injection electrode 4 to generate emission of light. More specifically, the organic semiconductor part 5 has an N-type organic semiconductor material layer 6 (N-type organic material layer) formed so as to contact the electron-injection electrode 3, a P-type organic semiconductor material layer 7 (P-type organic material layer) formed so as to contact the hole-injection electrode 4, and an organic light emitting material layer 8 provided there between. The P-type organic semiconductor material layer 7 is formed so as to cover the top surface of the hole-injection electrode 4 and the side face thereof facing the electron-injection electrode 3, and further to extend toward the electron-injection electrode 3 on the silicon oxide film 2 between the electrodes 3 and 4. The leading end part thereof reaches an intermediate part 11 of an interelectrode region 10 (channel) between the electrodes 3 and 4. The organic light emitting material layer 8 covers the P-type organic semiconductor material layer 7, and further contacts the silicon oxide film 2 at a region on the side of the electron-injection electrode 3 from the intermediate part 11 of the interelectrode region 10, and the leading end thereof reaches the electron-injection electrode 3. Then, the N-type organic semiconductor material layer 6 covers the top surface of the electron-injection electrode 3 and the side face thereof facing the hole-injection electrode 4, and further extends toward the hole-injection electrode 4 so as to cover the organic light emitting material layer 8. Accordingly, the N-type organic semiconductor material layer 6 and the P-type organic semiconductor material layer 7 have a PN-junction region 12 on a region from the intermediate part 11 up to the hole-injection electrode 4 in the interelectrode region 10. In addition, in FIG. 1, a midpoint position between the electron-injection electrode 3 and the hole-injection electrode 4 is illustrated as the intermediate part 11. However, generally, the term “intermediate part 11” means any position within a range, centered at the midpoint position between the electron-injection electrode 3 and the hole-injection electrode 4, with a half width of the interelectrode region 10. Hereinafter, in the other embodiments, the same is applied.

The N-type organic semiconductor material layer 6 functions as an electron transport layer capable of transporting electrons to at least the vicinity of the intermediate part 11. The P-type organic semiconductor material layer 7 functions as a hole transport layer capable of transporting holes to at least the vicinity of the intermediate part 11. The organic light emitting material layer 8 receives electrons from the N-type organic semiconductor material layer 6, and receives holes from the P-type organic semiconductor material layer 7, and recombines those to generate emission of light. The organic light emitting material layer 8 is not necessarily provided with a carrier transport capability. However, the organic light emitting material layer 8 is preferably formed of an organic semiconductor material with light emitting quantum efficiency higher than those of the N-type organic semiconductor material layer 6 and the P-type organic semiconductor material layer 7.

The gate electrode 1 is integrally formed so as to face the organic semiconductor part 5 via the silicon oxide film 2 at least at the interelectrode region 10. During a light emitting operation, for example, a negative gate control voltage Vg is applied to the gate electrode 1 from a gate control circuit 15, and a bias voltage Vd to make the hole-injection electrode 4 side positive is applied to the portion between the electrodes 3 and 4 from a biasing circuit 16. In accordance therewith, electrons are injected from the electron-injection electrode 3 into the N-type organic semiconductor material layer 6, and holes are injected from the hole-injection electrode 4 into the P-type organic semiconductor material layer 7. In the N-type organic semiconductor material layer 6, the electrons are transported toward the hole-injection electrode 4, and in the P-type organic semiconductor material layer 7, the holes are transported toward the electron-injection electrode 3.

At this time, because the P-type organic semiconductor material layer 7 is formed only up to the intermediate part 11 of the interelectrode region 10, the holes are dammed up to be accumulated at a leading edge 7a on the side of the electron-injection electrode 3. Therefore, in the vicinity of the intermediate part 11, recombination of the holes and the electrons in the organic semiconductor light emitting layer 7 intensively occur, which achieves effective emission of light. That is, the portion in the vicinity of the intermediate part 11 in the PN-junction region 12 generally contributes to emission of light.

In this way, in accordance with this embodiment, the invention is structured such that electrons are transported to the intermediate part 11 of the interelectrode region 10 (channel) by the N-type organic semiconductor material layer 6, and holes are transported to the intermediate part 11 of the interelectrode region 10 by the P-type organic semiconductor material layer 7, and those are recombined in the organic light emitting material layer 8 in the vicinity of the intermediate part 11. Accordingly, it is possible to efficiently transport both of the electrons and holes, and it is possible to recombine those at high efficiency. Additionally, by appropriately selecting the materials for the N-type organic semiconductor material layer 6 and the P-type organic semiconductor material layer 7, it is possible to easily make appropriate a carrier injection balance. In addition thereto, as needed, it is possible to select a material with high efficiency of electron-injection into the N-type organic semiconductor material layer 6 as a material of the electron-injection electrode 3, and to select a material with high efficiency of hole-injection into the P-type organic semiconductor material layer 7 as a material of the hole-injection electrode 4. Further, it has no difficulty to select such materials. Therefore, it is possible to realize an extremely highly efficient emission of light as a whole.

The electron-injection electrode 3 and the hole-injection electrode 4 can be both composed of, for example, electrodes of Au. Further, the N-type organic semiconductor material layer 6 can be composed of, for example, a C₆-NTC layer (whose layer thickness is, for example, 50 nm), and additionally, any material selected from the following N-type organic materials may be used as a construction material.

NTCDI based materials such as NTCDI, C₆-NTC, C₈-NTC, F₁₅-octyl-NTC, F₃-MeBn-NTC. PTCDI based materials such as PTCDI, C₆-PTC, C₈-PTC, C₁₂-PTC, C₁₃-PTC, Bu-PTC, F₇Bu-PTC, Ph-PTC, F₅Ph-PTC. Other examples are TCNQ, C₆₀-fullerene, F₁₆-CuPc, F₁₄-Pentacene, and the like.

Moreover, the P-type organic semiconductor material layer 7 can be composed of, for example, a pentacene layer (whose layer thickness is, for example, 50 nm), and additionally, any material selected from the following P-type organic materials may be used as a construction material.

Acene based materials such as pentacene, tetracene, and anthracene. Phthalocyanine based materials such as copper phthalocyanine. Oligothiophene materials such as α-sexithiophene, α,ω-dihexyl-sexithiophene, dihexyl-anthradithiophene, Bis(dithienothiophene), and α,ω-dihexyl-quinquethiophene. Polythiophene materials such as poly(3-hexylthiophene), and poly(3-butylthiophene). Other examples are low molecular materials such as oligophenylene, oligophenylenevinylene, TPD, α-NPD, m-MTDATA, TPAC, and TCTA, and high molecular materials such as poly(phenylenevinylene), poly(thienylenevinylene), polyacetylene, and poly(vinylcarbazole).

The organic light emitting material layer 8 is a layer formed of an organic semiconductor material with light emitting quantum efficiency higher than those of the N-type organic semiconductor material layer 6 and the P-type organic semiconductor material layer 7. More specifically, the organic light emitting material layer 8 is a layer formed of a material having an electric characteristic in which a HOMO-LUMO gap is narrower than those of the N-type organic semiconductor material layer 6 and the P-type organic semiconductor material layer 7 so as to be possible to confine charges. For example, the organic light emitting material layer 8 may be composed of a laminated structure film in which a TPD film (whose film thickness is, for example, 15 nm) and an Alq₃ film (an electron-ejection material layer disposed on the N-type organic semiconductor material layer 6 side, whose film thickness is, for example, 15 nm) are laminated. More generally, the organic light emitting material layer 8 preferably has a single layer or a composite layer (a multilayer laminated film) including at least one of a metal complex based material film emitting fluorescent light such as Tris(8-hydroxyquinolinato)aluminum(III)(Alq₃), a film in which another fluorescent dye such as DCM2, Rubrene, Coumaline, or Perylene is doped on such a metal complex based material, and a film in which a phosphorescence emitting dye such as fac-tris(2-phenypyridine)iridium (Ir(ppy)₃) is doped on 4,4′-Bis(carbazol-9-yl)biphenyl(CBP).

Moreover, the organic light emitting material layer 8 may have a hole transport material layer provided between it and the P-type organic semiconductor material layer 7, and may be structured such that a hole transport material and a luminescent material are mixed to form a film. In accordance with such a structure, it is possible to adjust the amount of carriers supplied to a light emitting region, and to prevent luminescent decay due to charges by separating the emitting region away from the P-type material and the N-type material rich in charges. As a hole transport material, diamine based materials including a-NPD and TPD can be mentioned.

For the same purpose, the organic light emitting material layer 8 may have an electron transport layer provided between it and the N-type organic semiconductor material layer 6 (m-TDATA or the like), and may be structured such that an electron transport material and a luminescent material are mixed to form a film. As an electron transport material, oxadiazole based materials including PBD, triazole based materials including TAZ, 4,7-Diphenyl-1,10-phenanthroline (Bathophenantholine), and the like can be mentioned.

Moreover, in order to facilitate the injection of holes from the P-type organic semiconductor material layer 7 into the organic light emitting material layer 8, a layer of Copper Phthalocyanine, m-MTDATA, or the like (whose layer thickness is, for example, 1 nm or less) may be provided as a hole injection layer between them. Moreover, in order to facilitate the injection of electrons from the N-type organic semiconductor material layer 6 into the organic light emitting material layer 8, an electron injection layer may be provided between them. As an electron injection layer, a layer in which alkaline metal such as lithium (Li) or cesium (Cs) is doped in an electron transport property organic semiconductor of Alq₃ or Bathophenanthroline, or a layer of alkaline metal/alkali earth metal fluoride including lithium fluoride (LiF), germanium oxide (GeO), aluminum oxide (A₂lO₃), or the like can be mentioned.

The electron-injection electrode 3 and the hole-injection electrode 4 may be comb-shaped electrodes each including a base and a plurality of linear portions parallel to one another which extend from the base. The both electrodes 3 and 4 may be formed in such a manner that the linear portions of the electron-injection electrode 3 and the hole-injection electrode 4 which are formed as comb-shaped electrodes are formed on the substrate so as to be engaged with one another with fine gaps (for example, approximately 10 μm).

FIG. 2 is a graph showing an example of operating characteristics of the organic semiconductor light emitting element of FIG. 1. Interelectrode bias voltages Vd (volts) are plotted in abscissa, and emission intensities (arbitrary unit) are plotted in ordinate, and the results of measuring characteristics with respect to various gate voltages Vg (volts) are shown. It can be understood from FIG. 2 that it is possible to modulate emission intensity in accordance with a gate voltage Vg, and that when a voltage value is appropriately selected, on/off control of emission of light is possible.

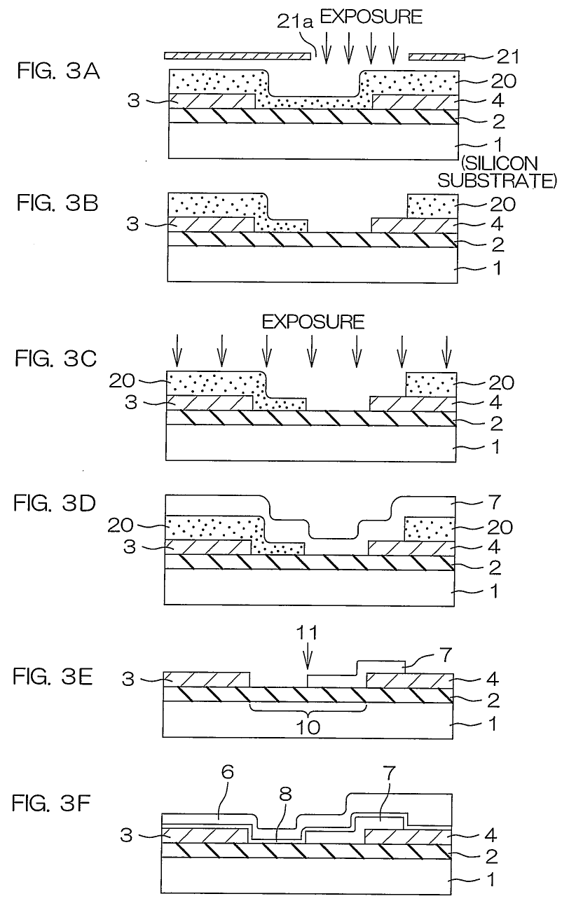

FIGS. 3A to 3F are schematic sectional views showing a method for manufacturing the organic semiconductor light emitting element in the order of steps. First, as shown in FIG. 3A, the silicon oxide film 2 is formed on a silicon substrate in which the gate electrode 1 composed of an impurity diffused layer is formed on its surface by injecting N-type impurity in high concentration, and the electron-injection electrode 3 and the hole-injection electrode 4 in predetermined patterns are formed with a space on the silicon oxide film 2. Then, in this state, a photoresist 20 is applied onto a region from the electron-injection electrode 3 up to the hole-injection electrode 4. A photomask 21 is disposed above the substrate in this state, and the photoresist 20 is selectively exposed to light. That is, an opening 21a in a shape corresponding to the P-type organic semiconductor material layer 7 is formed in the photomask 21, and the photoresist 20 at a region corresponding to the opening 21a is selectively exposed to ultra violet light. The photoresist 20 induces a chemical change in itself to be soluble in an alkaline developer by being exposed to ultra violet light.

Next, as shown in FIG. 3B, the hole-injection electrode 4 becomes exposed by developing the photoresist 20 using an alkaline developer. At this time, the photoresist 20 is developed to be a pattern (reversal pattern) in which the pattern of the P-type organic semiconductor material layer 7 is reversed. Thereafter, an HMDS (hexamethyldisilazane (silane coupling agent), that is, adhesion improving embrocation) treatment is further executed as a surface treatment to enhance adhesion between the P-type organic semiconductor material layer 7 which is formed next and the silicon oxide film 2. Moreover, a surface treatment using a thiol compound is executed in order to enhance adhesion between the P-type organic semiconductor material layer 7 and the hole-injection electrode 4 (which is formed of, for example, Au).

Thereafter, as shown in FIG. 3C, the entire surface is exposed to ultra violet light, and all of the photoresist 20 on the substrate is exposed to ultra violet light.

Next, as shown in FIG. 3D, the P-type organic semiconductor material layer 7 is vapor-deposited on the entire surface. Moreover, as shown in FIG. 3E, the photoresist 20 is dissolved by using an alkaline developer. In accordance therewith, an unnecessary portion of the P-type organic semiconductor material layer 7 is lifted off. Because the photoresist 20 has been exposed to ultra violet light in advance in the step of FIG. 3C, the photoresist 20 is easily dissolved in the alkaline developer. Further, because the HMDS treatment and the surface treatment using a thiol compound have been executed before the P-type organic semiconductor material layer 7 is formed, the coupling of the silicon oxide film 2 and the hole-injection electrode 4 with respect to the P-type organic semiconductor material layer 7 is firmly retained even during the lift-off process. In this way, it is possible to form the P-type organic semiconductor material layer 7 at the region from the hole-injection electrode 4 up to the intermediate part 11 of the interelectrode region 10.

Thereafter, as shown in FIG. 3F, the organic light emitting material layer 8 and the N-type organic semiconductor material layer 6 are vapor-deposited on the entire surface in this order, which completes an organic semiconductor light emitting element.

In the construction of FIG. 3F, the organic light emitting material layer 8 is provided between the electron-injection electrode 3 and the N-type organic semiconductor material layer 6. However, because the electrons pass through the organic light emitting material layer 8, and are injected from the electron-injection electrode 3 into the N-type organic semiconductor material layer 6, there is no operational problem. As a matter of course, as shown in FIG. 1, the organic light emitting material layer 8 is not necessarily formed on the top surface of the electron-injection electrode 3.

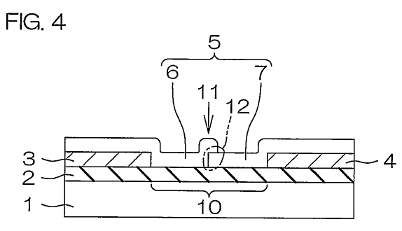

FIG. 4 is a schematic sectional view for explanation of a construction of an organic semiconductor light emitting element to which a method according to a second embodiment of the present invention is applied. In FIG. 4, portions corresponding to the respective parts shown in FIG. 1 described above are denoted by the same reference numerals as in FIG. 1.

In this organic semiconductor light emitting element, an organic light emitting material layer is not provided, and the P-type organic semiconductor material layer 7 and the N-type organic semiconductor material layer 6 are directly jointed at the intermediate part 11 of the interelectrode region 10 to form the PN-junction region 12. Further, the leading edge of the N-type organic semiconductor material layer 6 is positioned at the intermediate part 11, and does not reach the hole-injection electrode 4. That is, in this embodiment, the N-type organic semiconductor material layer 6 and the P-type organic semiconductor material layer 7 do not substantially have a laminated area at which they are laminated with each other.

In accordance with this construction, the holes injected into the P-type organic semiconductor material layer 7 by the hole-injection electrode 4 are accumulated at the leading edge in the vicinity of the intermediate part 11, and the electrons injected into the N-type organic semiconductor material layer 6 by the electron-injection electrode 3 are accumulated at the leading edge in the vicinity of the intermediate part 11. In accordance therewith, highly efficient emission of light is made possible by recombination of the holes and the electrons in the PN-junction region 12.

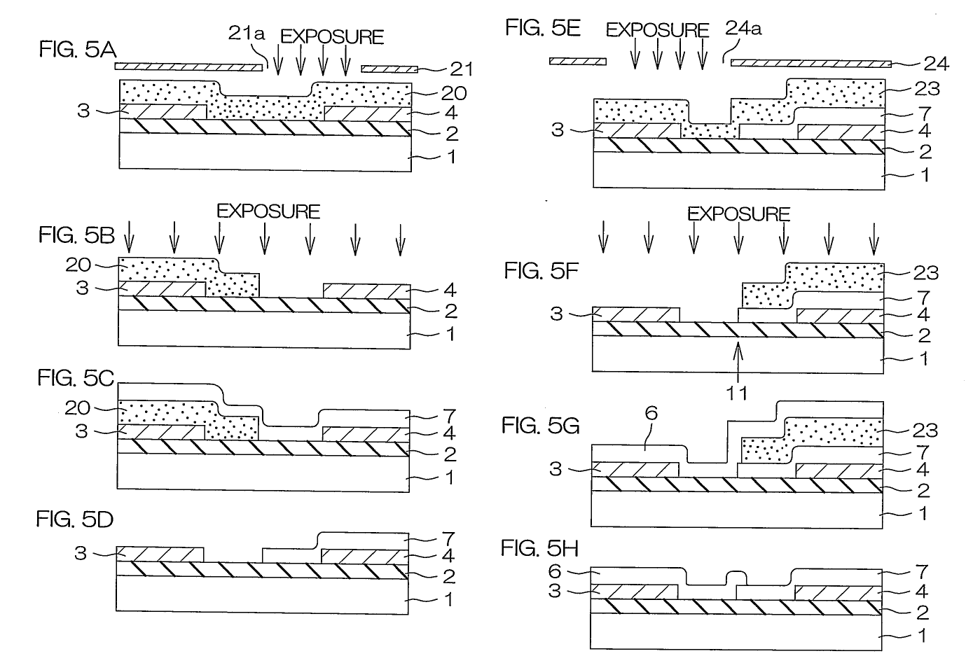

FIGS. 5A to 5H are schematic sectional views showing a method for manufacturing the organic semiconductor light emitting element of FIG. 4 in the order of steps. The steps of FIGS. 5A to 5D are the same as the steps of FIGS. 3A to 3E. Thereafter, as shown in FIG. 5E, a photoresist 23 is applied onto the entire surface, and exposure to ultra violet light is carried out by using a photomask 24 as a mask. An opening 24a is formed at a region corresponding to the N-type organic semiconductor material layer 6 in the photomask 24, and a region corresponding to the opening 24a is exposed to ultra violet light. The photoresist 23 induces a chemical change in itself to be soluble in an alkaline developer by being exposed to ultra violet light.

Next, as shown in FIG. 5F, the photoresist 23 is developed with an alkaline developer. In accordance therewith, the photoresist 23 at a region from the electron-injection electrode 3 up to the intermediate part 11 is peeled off, and the electron-injection electrode 3 and a region of the silicon oxide film 2 on the side of the electron-injection electrode 3 become exposed. At this time, the photoresist 23 is developed to have a reversal pattern of the pattern of the N-type organic semiconductor material layer 6.

After this development, an adhesion enhancing treatment using HMDS is executed as a surface treatment to enhance adhesion between the N-type organic semiconductor material layer 6 which is formed next and the silicon oxide film 2. Moreover, a surface treatment using a thiol compound is executed in order to enhance adhesion between the N-type organic semiconductor material layer 6 and the electrode injection electrode 3 (which is formed of, for example, Au). Thereafter, the entire surface is exposed to ultra violet light. In accordance therewith, the entire photoresist 23 is exposed to ultra violet light.

Next, as shown in FIG. 5G, the N-type organic semiconductor material layer 6 is vapor-deposited on the entire surface. Thereafter, as shown in FIG. 5H, the photoresist 23 is dissolved by using an alkaline developer. In accordance therewith, an unnecessary portion of the N-type organic semiconductor material layer 6 is lifted off, and an organic semiconductor light emitting element having the construction of FIG. 4 is obtained. In this lift-off process, the two types of organic semiconductor material layers of the N-type organic semiconductor material layer 6 and the P-type organic semiconductor material layer 7 are formed on the substrate. However, because the aforementioned process of exposing the entire surface to ultra violet light has been carried out, it is possible to increase the selectivity of the photoresist 23 with respect to both the two types of organic semiconductor material layers 6 and 7. Accordingly, it is possible to dissolve the photoresist 23 and to lift off the N-type organic semiconductor material layer 6 without causing substantially any damage to the organic semiconductor material layers 6 and 7.

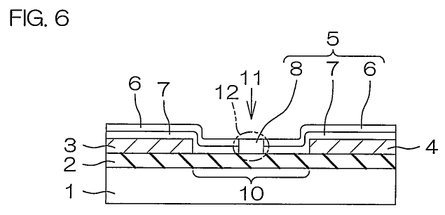

FIG. 6 is a schematic sectional view showing a construction of an organic semiconductor light emitting element to which a method according to a third embodiment of the present invention is applied. In FIG. 6, portions corresponding to the respective parts shown in FIG. 1 described above are denoted by the same reference numerals as in FIG. 1.

In this organic semiconductor light emitting element, the organic light emitting material layer 8 contacting the silicon oxide film 2 is disposed at the intermediate part 11 so as to divide the interelectrode region 10 in two. Laminated structure films of the P-type organic semiconductor material layer 7 and the N-type organic semiconductor material layer 6 are formed on both the sides of the organic light emitting material layer 8. Accordingly, the P-type organic semiconductor material layer 7 contacts both of the hole-injection electrode 4 and the electron-injection electrode 3. Further, a region in the vicinity of the organic light emitting material layer 8 serves as the PN-junction region 12 between the P-type organic semiconductor material layer 7 on the side of the hole-injection electrode 4 and the N-type organic semiconductor material layer 6 on the side of the electron-injection electrode 3.

The organic light emitting material layer 8 is a material with low carrier mobility but high light emitting quantum efficiency. Therefore, the holes injected from the hole-injection electrode 4 into the P-type organic semiconductor material layer 7 contacted thereto are dammed up at the organic light emitting material layer 8 to be accumulated at the leading edge thereof. On the other hand, electrons pass through the P-type organic semiconductor material layer 7 on the side of the electron-injection electrode 3 to be injected into the N-type organic semiconductor material layer 6. The electrons go toward the hole-injection electrode 4, but are dammed up at the organic light emitting material layer 8 to be accumulated at the leading edge thereof. In this way, with the organic light emitting material layer 8 sandwiched there between, holes are stored abundantly on the side of the hole-injection electrode 4, and electrons are stored abundantly on the side of the electron-injection electrode 3. When those are recombined in the organic light emitting material layer 8 with high light emitting quantum efficiency, highly efficient emission of light is made possible.

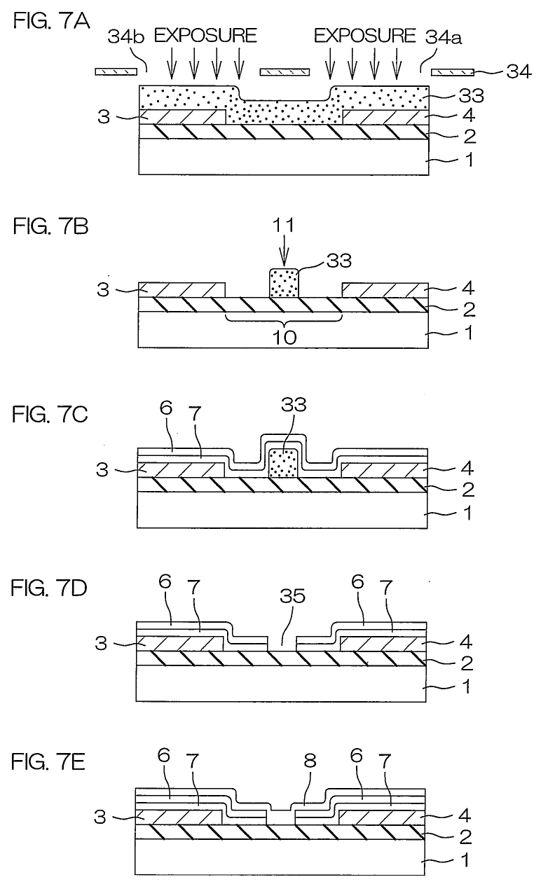

FIGS. 7A to 7E are schematic sectional views showing a method for manufacturing the organic semiconductor light emitting element of FIG. 6 in the order of steps. First, as shown in FIG. 7A, the silicon oxide film 2 is formed on a silicon substrate in which the gate electrode 1 composed of an impurity diffused layer is formed on its surface by injecting N-type impurity in high concentration, and the electron-injection electrode 3 and the hole-injection electrode 4 in predetermined patterns are formed with a space on the silicon oxide film 2. Then, in this state, a photoresist 33 is applied onto a region from the electron-injection electrode 3 up to the hole-injection electrode 4. A photomask 34 is disposed above the substrate in this state, and the photoresist 33 is selectively exposed to light. That is, an opening 34a in a shape corresponding to the P-type organic semiconductor material layer 7 and an opening 34b corresponding to the N-type organic semiconductor material layer 6 are formed in the photomask 34, and the photoresist 33 at regions corresponding to these openings 34a and 34b is selectively exposed to ultra violet light. The photoresist 33 induces a chemical change in itself to be soluble in an alkaline developer by being exposed to ultra violet light.

Next, as shown in FIG. 7B, the hole-injection electrode 4 and the electron-injection electrode 3 become exposed by developing the photoresist 33 with an alkaline developer. At this time, the photoresist 33 corresponding to a reversal pattern of the laminated structure film of the N-type organic semiconductor material layer 6 and the P-type organic semiconductor material layer 7 remains at the intermediate part 11 of the interelectrode region 10, and the silicon oxide film 2 becomes exposed at a region between the electron-injection electrode 3 and the hole-injection electrode 4 on the both sides thereof.

Thereafter, an HMDS treatment is further executed as a surface treatment to enhance adhesion between the P-type organic semiconductor material layer 7 which is formed next and the silicon oxide film 2. Moreover, a surface treatment using a thiol compound is executed in order to enhance adhesion between the P-type organic semiconductor material layer 7 and the hole-injection electrode 4, and between the P-type organic semiconductor material layer 7 and the electron-injection electrode 3 (the electrodes 3 and 4 are both formed of, for example, Au). Thereafter, the entire surface is exposed to ultra violet light.

Next, as shown in FIG. 7C, the P-type organic semiconductor material layer 7 and the N-type organic semiconductor material layer 6 are formed to be laminated in this order on the entire surface. Moreover, as shown in FIG. 7D, the photoresist 33 is dissolved by using an alkaline developer. In accordance therewith, unnecessary portions of the P-type organic semiconductor material layer 7 and the N-type organic semiconductor material layer 6 are lifted off. In this way, a laminated structure film (a film in which the organic semiconductor material layers 6 and 7 are laminated) having a gap 35 at the intermediate part 11 of the interelectrode region 10 is obtained.

In the lift-off process, two types of the N-type organic semiconductor material layer 6 and the P-type organic semiconductor material layer 7 are formed on the substrate. However, because the aforementioned process exposing the entire surface to ultra violet light has been carried out, it is possible to increase the selectivity for the photoresist 23 with respect to both the two types of organic semiconductor material layers 6 and 7. Accordingly, it is possible to dissolve the photoresist 23 and to lift off the two types of organic semiconductor material layers 6 and 7 collectively without causing any substantially damage to the organic semiconductor material layers 6 and 7.

Thereafter, as shown in FIG. 7E, when the organic light emitting material layer 8 is vapor-deposited on the entire surface, the organic light emitting material layer 8 enters the gap 35, and a construction which is the same as that of the organic semiconductor light emitting element of FIG. 6 is obtained.

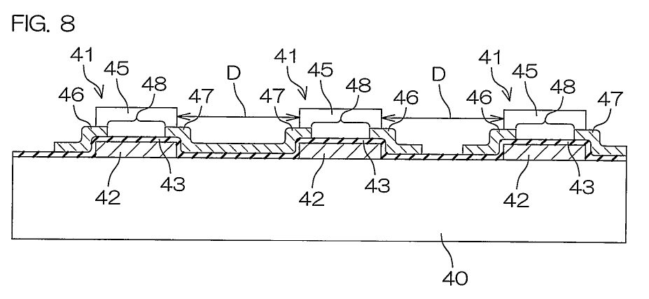

FIG. 8 is a schematic sectional view showing an organic semiconductor integrated circuit element to which a method according to a fourth embodiment of the present invention is applied. This organic semiconductor integrated circuit element is structured such that a plurality of organic semiconductor transistors 41 are formed on a substrate 40 (for example, a glass substrate or a silicon substrate). Each of the organic semiconductor transistors 41 includes a gate electrode 42 formed on the substrate 40, an organic semiconductor material layer 45 disposed to face the gate electrode 42 via a gate insulating film 43 (which is formed of, for example, silicon oxide), and a pair of electrodes 46 and 47 (a source electrode and a drain electrode) contacting the organic semiconductor material layer 45. The electrodes 46 and 47 are disposed to face each other with a space with a predetermined channel region 48 facing the gate electrode 42 in the organic semiconductor material layer 45 sandwiched there between.

For the purpose of making the respective organic semiconductor transistors 41 electrically isolated, the organic semiconductor material layers 45 of the organic semiconductor transistors 41 adjacent to one another are separated from one another with a distance D. This distance D is in the order of, for example, 1 micrometer, and in accordance therewith, an organic semiconductor integrated circuit element according to a submicron design rule is structured.

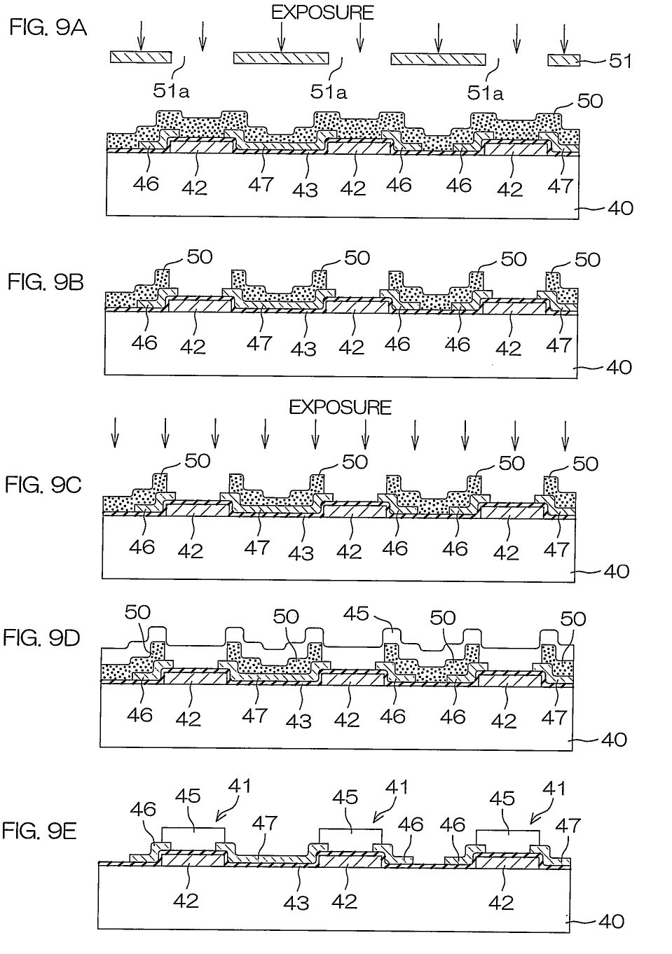

FIGS. 9A to 9E are schematic sectional views showing the process for forming the organic semiconductor material layers 45 in the organic semiconductor integrated circuit element of FIG. 8 in the order of steps. First, as shown in FIG. 9A, a photoresist 50 is applied onto the entire surface of the surface of the substrate 40 on which the gate electrodes 42, the gate insulating film 43, and the electrodes 46 and 47 are formed (precisely, the surfaces of the gate insulating film 43 and the electrodes 46 and 47). A photomask 51 is disposed above the substrate 40 in this state, and the photoresist 50 is selectively exposed to light. That is, openings 51a in shapes corresponding to the organic semiconductor material layers 45 are formed in the photomask 51, and the photoresist 50 at the regions corresponding to the openings 51a is selectively exposed to light. The photoresist 50 induces a chemical change in itself to be soluble in an alkaline developer by being exposed to ultra violet light.

Next, as shown in FIG. 9B, the electrodes 46 and 47 become partly exposed respectively by developing the photoresist 50 using an alkaline developer. At this time, the photoresist 50 is developed to have a pattern (a reversal pattern) in which the pattern of the organic semiconductor material layer 45 to be formed is reversed. Thereafter, an HMDS treatment is further executed as a surface treatment to enhance adhesion between the organic semiconductor material layer 45 which is formed next and the gate insulating film 43. Moreover, a surface treatment using a thiol compound is executed in order to enhance adhesion between the organic semiconductor material layer 45 and the electrodes 46 and 47 (which are formed of, for example, Au).

Thereafter, as shown in FIG. 9C, the entire surface is exposed to ultra violet light, and all of the photoresist 50 on the substrate 40 is exposed to ultra violet light.

Next, as shown in FIG. 9D, the organic semiconductor material layer 45 is vapor-deposited on the entire surface. Moreover, as shown in FIG. 9E, the photoresist 50 is dissolved by using an alkaline developer. In accordance therewith, unnecessary portions of the organic semiconductor material layer 45 is lifted off. Because the photoresist 50 has been exposed to ultra violet light in advance in the step of FIG. 9C, the photoresist 50 is easily dissolved in the alkaline developer to be removed with high selectivity to the organic semiconductor material layer 45. Further, because the HMDS treatment and the surface treatment using a thiol compound have been executed before the organic semiconductor material layer 45 is formed, the coupling of the organic semiconductor material layers 45 with respect to the gate insulating film 43, and the electrodes 46 and 47 is firmly retained even during the lift-off process. In this way, it is possible to form the organic semiconductor material layers 45 contacting these electrodes 46 and 47 on the region between the electrodes 46 and 47 of each organic semiconductor transistor 41.

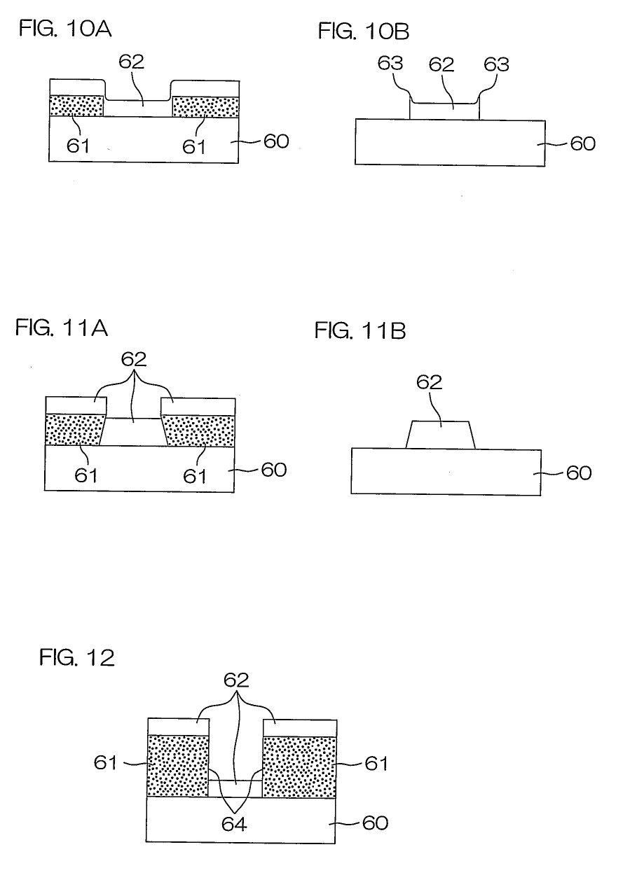

FIGS. 10A and 10B, and FIGS. 11A and 11B are schematic sectional views for explanation of a method according to a fifth embodiment of the present invention. As shown in FIG. 10A, patterns of resist films 61 whose sections are substantially rectangular are formed on a substrate 60, and when an organic material layer 62 is deposited thereon and then lifted off, as shown in FIG. 10B, protrusions 63 are formed on the edge portions of the patterned organic material layer 62 in some cases. When this is problematic, as shown in FIG. 11A, the resist films 61 are preferably formed into substantially inversed trapezoidal shapes in sections. In accordance therewith, as shown in FIG. 11B, it is possible for the organic material layer 62 after the lift-off process to have a satisfactory sectional shape without any protrusion on it sedge parts. For the formation of the resist films 61 in inversed trapezoidal shapes in sections, a well-known method as disclosed in, for example, Patent Document 2 or Patent Document 3 can be used.

An other method for suppressing or preventing protrusions on the edge parts of the organic material layer 62 is, as shown in FIG. 12, such that the resist films 61 are formed to be thicker (for example, 10 or more in a layer thickness ratio to the organic material layer 62) than a layer thickness of the organic material layer 62 to be formed. In this case, because layer thicknesses of the portions of the organic material layer adhered to side walls 64 of the patterns of the resist films 61 are made extremely thin, the portions of the organic material layer are removed along with the resist films 61 in the lift-off process. In this way, it is possible to suppress or prevent protrusions from being formed.

A detailed description has been given of embodiments of the present invention. However, these embodiments are only detailed examples used to make apparent the technical features of the present invention, the present invention should not be interpreted as being limited to these detailed examples, and the spirit and the scope of the present invention are limited only by the scope of claims attached hereto.

The present application corresponds to Japanese Patent Application No. 2005-249550 submitted to Japanese Patent Office on Aug. 30, 2005, and all the disclosures in this application are to be incorporated herein by reference.

1. An organic material layer formation method for forming a pattern of an organic material layer on a substrate, the method comprising the steps of:
forming a resist in a reversal pattern of an organic material layer pattern to be formed on the substrate;
applying a surface treatment onto an exposed area exposed from the resist on a surface of the substrate to enhance adhesion to an organic material;
forming an organic material layer on the resist and the exposed area; and
selectively dissolving the resist with an aqueous solution having selectivity between the organic material and the resist, to lift off the organic material layer on the resist along with the resist.

2. The organic material layer formation method according to claim 1, further comprising an entire resist exposure step of exposing all of the resist on the substrate before the lift-off step to induce a chemical change in the resist to be soluble in the aqueous solution.

3. The organic material layer formation method according to claim 2, wherein the aqueous solution is an alkaline aqueous solution.

4. The organic material layer formation method according to claim 3, wherein
on the exposed area, one or more of silicon oxide, alumina, and silicon oxide nitride become exposed from the resist, and
the surface treatment includes a surface treatment using a silane coupling agent.

5. The organic material layer formation method according to claim 4, wherein gold is exposed on the exposed area, and
the surface treatment includes a surface treatment using a thiol compound.

6. The organic material layer formation method according to claim 1, wherein the aqueous solution is an alkaline aqueous solution.

7. The organic material layer formation method according to claim 6, wherein
on the exposed area, one or more of silicon oxide, alumina, and silicon oxide nitride become exposed from the resist, and
the surface treatment includes a surface treatment using a silane coupling agent.

8. The organic material layer formation method according to claim 2, wherein
on the exposed area, one or more of silicon oxide, alumina, and silicon oxide nitride become exposed from the resist, and
the surface treatment includes a surface treatment using a silane coupling agent.

9. The organic material layer formation method according to claim 1, wherein
on the exposed area, one or more of silicon oxide, alumina, and silicon oxide nitride become exposed from the resist, and
the surface treatment includes a surface treatment using a silane coupling agent.

10. The organic material layer formation method according to claim 9, wherein gold is exposed on the exposed area, and
the surface treatment includes a surface treatment using a thiol compound.

11. The organic material layer formation method according to claim 8, wherein gold is exposed on the exposed area, and
the surface treatment includes a surface treatment using a thiol compound.

12. The organic material layer formation method according to claim 7, wherein gold is exposed on the exposed area, and
the surface treatment includes a surface treatment using a thiol compound.

13. The organic material layer formation method according to claim 6, wherein gold is exposed on the exposed area, and
the surface treatment includes a surface treatment using a thiol compound.

14. The organic material layer formation method according to claim 3, wherein gold is exposed on the exposed area, and
the surface treatment includes a surface treatment using a thiol compound.

15. The organic material layer formation method according to claim 2, wherein gold is exposed on the exposed area, and
the surface treatment includes a surface treatment using a thiol compound.

16. The organic material layer formation method according to claim 1, wherein gold is exposed on the exposed area, and
the surface treatment includes a surface treatment using a thiol compound.
